(19) United States
(12) Patent Application Publication
(10) Pub. No.: US 2010/0252100 A1
(43) Pub. Date: Oct. 7, 2010

(54) MULTI-LAYER THIN FILM FOR PHOTOVOLTAIC CELL

(75) Inventors: Je Choon Ryoo, ChungCheongNam-Do (KR); Jin Soo An, ChungCheongNam-Do (KR)

Correspondence Address: LERNER, DAVID, LITTENBERG,;KRUMHOLZ & MENTLIK, 600 SOUTH AVENUE WEST, WESTFIELD, NJ, 07090, US

(73) Assignee: SAMSUNG CORNING PRECISION GLASS CO., LTD., Gyeongsangbuk-do (KR)

(21) Appl. No.: 12/732,483

(22) Filed: Mar. 26, 2010

(30) Foreign Application Priority Data
Apr. 2, 2009 (KR) 10-2009-0028562

(51) Int. Cl. H01L 31/00

(52) U.S. Cl. 136/256

(57) ABSTRACT

A multilayer thin film for a photovoltaic cell includes a plurality of low-refractivity thin film layers and a plurality of high-refractivity thin film layers alternately coating a transparent substrate. The thickest layer of the low-refractivity thin film layers is thicker than all of the high-refractivity thin film layers and is one and half times thicker than all of the other layers of the low-refractivity thin film layers.

### CROSS REFERENCE TO RELATED APPLICATION

The present application claims priority from Korean Patent Application Number 10-2009-0028562 filed on Apr. 2, 2009, the entire contents of which application is incorporated herein for all purposes by this reference.

### BACKGROUND OF THE INVENTION

1. Field of the Invention

The present invention relates to a photovoltaic cell and, more particularly, to a multi-layer thin film for a photovoltaic cell that blocks ultraviolet light in order to prevent an Ethylene Vinyl Acetate (EVA) sheet, which is used as a buffer material in the photovoltaic cell, from becoming discolored.

2. Description of Related Art

A photovoltaic cell is a power-generating device that converts light energy into voltage and current. Photovoltaic cells, especially silicon solar cells can generally be classified into bulk solar cells, which use monocrystalline or polycrystalline silicon, and thin film solar cells, which are formed by the deposition of a thin film or the like. In the case of the bulk solar cell, cells are connected during the process of fabricating modules, generally using aluminum ribbons. The aluminum ribbons are bonded to respective cells, thereby forming a series connection. In this case, the aluminum ribbons are required to be thick enough to maintain a low resistance in this series connection. Such a connecting step is performed during the process of fabricating the module, which is a packing process of cells subsequent to the process of fabricating the cells. In contrast, the thin film solar cell is fabricated generally by one process in which the fabrication of a cell and the fabrication of a module are performed together. The costs of the separation and electrical connection between cells account for a great portion of the total cost of manufacturing the thin film solar cell.

FIG. 1 is a cross-sectional view showing the structure of a conventional silicon thin film photovoltaic cell 100.

The conventional thin film photovoltaic cell 100 includes a transparent substrate 110, an antireflection layer 120, an Ethylene Vinyl Acetate (EVA) sheet 125 used as a buffering material, and a photovoltaic element. The photovoltaic element includes transparent conductive oxide electrodes 131 and 132, a first electrode layer 141 and 142, power-generating regions 151 and 152, a second electrode layer 161 and 162, a conductor layer 171 and 172, and an insulating film 181.

The transparent substrate 110, typically, a glass substrate is formed to protect the photovoltaic element from external environmental factors such as moisture, dust, and impact. The antireflection layer 120 increases the amount of light that passes through the transparent substrate 110 by lowering the reflectance. The antireflection layer 120 can be formed by coating the surface of the transparent substrate 110 with a material such as SiO₂, Al₂O₃, Si₃N₄, or CeO₂, which has a low refractive index from 1.8 to 2.6. The EVA sheet 125 serves to protect the photovoltaic element from external environmental factors such as moisture, which would otherwise penetrate into the photovoltaic element, and serves as a seal bonding the antireflection film 120 to the photovoltaic element. The transparent conductive oxide layers 131 and 132 serve to maximize the effect of light trapping. The transparent conductive oxide layers 131 and 132 can be made of Indium-Tin Oxide (ITO), which is highly transparent to visible light and has a high electrical conductivity.

In general, the photovoltaic cell is required to maintain a photovoltaic efficiency equivalent to 80% or more of initial output for 20 years. Major factors that reduce the lifetime of the photovoltaic cell include the deterioration of the photovoltaic cell, discoloration of the EVA sheet, power loss caused by an increase in series resistance due to the oxidation of the electrodes, and the like. In particular, the EVA sheet, used as a buffer material in the photovoltaic cell, begins to age and discolor when exposed to ultraviolet light. Although whitening appears in limited areas of the EVA sheet in early stages, it becomes serious and spreads over the entire areas of the EVA sheet with time, thereby decreasing the amount of light transmitted through to reach the photovoltaic element. The problem is that this lowers the photovoltaic efficiency of the photovoltaic cell.

The information disclosed in this Background of the Invention section is only for the enhancement of understanding of the background of the invention and should not be taken as an acknowledgment or any form of suggestion that this information forms a prior art that would already be known to a person skilled in the art.

### BRIEF SUMMARY OF THE INVENTION

Various aspects of the present invention provide a multilayer thin film for a photovoltaic cell which coats the photovoltaic cell and blocks ultraviolet light to increase the lifetime of the photovoltaic cell.

Also provided is a multilayer thin film for a photovoltaic cell that not only blocks ultraviolet light but also prevents the reflection of visible light and blocks near infrared light.

In an aspect of the present invention, the multilayer thin film for a photovoltaic cell may include a plurality of low-refractivity thin film layers and a plurality of high-refractivity thin film layers alternately coating a transparent substrate. The thickest layer of the low-refractivity thin film layers can be thicker than all of the high-refractivity thin film layers and be one and half times thicker than all of the other layers of the low-refractivity thin film layers.

The multilayer thin film for a photovoltaic cell can block ultraviolet light, which would otherwise cause discoloration of an Ethylene Vinyl Acetate (EVA) sheet, thereby increasing the lifetime of the photovoltaic cell.

Furthermore, the multilayer thin film for a photovoltaic cell can raise the transmittance of visible light while blocking ultraviolet and near infrared light, which serves to raise the photovoltaic efficiency and at the same time, increase the lifetime of the photovoltaic cell.

The methods and apparatuses of the present invention have other features and advantages which will be apparent from, or are set forth in greater detail in, the accompanying drawings, which are incorporated herein and in the following Detailed Description of the Invention, which together serve to explain certain principles of the present invention.

### BRIEF DESCRIPTION OF THE DRAWINGS

FIG. 1 is a cross-sectional view showing the structure of a conventional silicon thin film photovoltaic cell;

FIG. 2 is a cross-sectional view showing the structure of a photovoltaic cell having a multilayer thin film according to an exemplary embodiment of the invention;

FIG. 3 is a cross-sectional view showing a multilayer thin film for a photovoltaic cell according to an exemplary embodiment of the invention;

FIG. 4A is a view showing the physical properties of a multilayer thin film for a photovoltaic cell according to an exemplary embodiment of the invention; and

FIG. 4B is a graph showing light transmittance, according to wavelength, of a transparent substrate having the multilayer thin film according to FIG. 4A.

### DETAILED DESCRIPTION OF THE INVENTION

Reference will now be made in detail to various embodiments of the present invention(s), examples of which are illustrated in the accompanying drawings and described below. While the invention(s) will be described in conjunction with exemplary embodiments, it will be understood that the present description is not intended to limit the invention(s) to those exemplary embodiments. On the contrary, the invention(s) is/are intended to cover not only the exemplary embodiments, but also various alternatives, modifications, equivalents and other embodiments that may be included within the spirit and scope of the invention as defined by the appended claims.

The present invention has realized a multilayer thin film for a photovoltaic cell by coating a transparent substrate alternately with a plurality of high-refractivity thin film layers and a plurality of low-refractivity thin film layers, in such a manner that the multilayer thin film can raise the transmittance of visible light and lower the transmittance of ultraviolet and near infrared light, thereby increasing the lifetime of the photovoltaic element. The number of the layers of the multi-layer thin film may be five to fifteen. Exemplary embodiments of the invention described herein will propose an optimum multi-layer thin film for a photovoltaic cell. In addition, in this specification, the high-refractivity thin film layers may have a refractive index ranging from 2.0 to 2.4, and the low-refractivity thin film layers may have a refractive index ranging from 1.38 to 1.46.

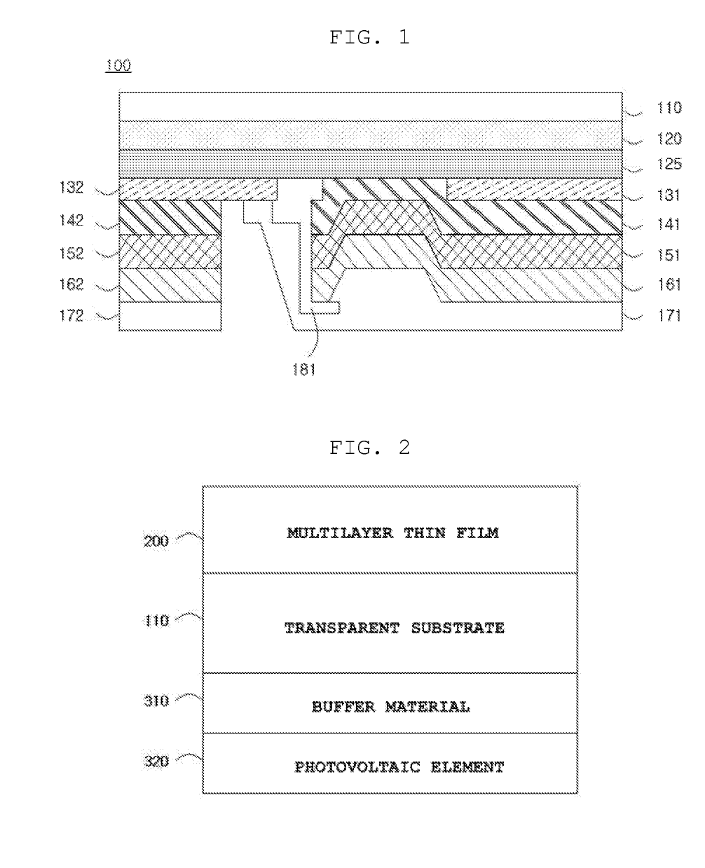

FIG. 2 is a cross-sectional view showing the structure of a photovoltaic cell having a multilayer thin film according to an exemplary embodiment of the invention.

As shown in the figure, the photovoltaic cell includes a transparent substrate 110, a multilayer thin film 200, a buffer material 310, and a photovoltaic element 300. Although not shown in FIG. 2, a glass substrate, which protects the photovoltaic element 300, can be attached to the rear surface of the photovoltaic element 300.

The transparent substrate 110 can be a glass substrate and protect the photovoltaic element 300 from external environmental factors such as moisture, dust, and impact. The multilayer thin film 200 is a key part of the invention that raises the transmittance of visible light while blocking ultraviolet and near infrared light. The multilayer thin film can be formed to coat the transparent substrate 110 by, for example, vacuum deposition, sputtering, vapor deposition, spin coating, sol-gel dipping, Plasma Enhanced Chemical Vapor Deposition (PECVD), and or like.

The buffer material 310 such as, for example, an Ethylene Vinyl Acetate (EVA) sheet serves to protect the photovoltaic element 300 from external environmental factors such as moisture, which would otherwise penetrate into the photovoltaic element, and serves as a seal bonding the transparent substrate 110 to the photovoltaic element 320. The photovoltaic element 300 functions as a power-generating element that converts the energy of sunlight into voltage and current. The photovoltaic element can include, for example, transparent conductive oxide electrodes, a first electrode layer, power-generating regions, a second electrode layer, a conductor layer, and an insulating film. However, the photovoltaic element according to the present invention is not limited to such a type. Since various structures of the photovoltaic element 300 were well known in the art prior to this application, a detailed description thereof will be omitted.

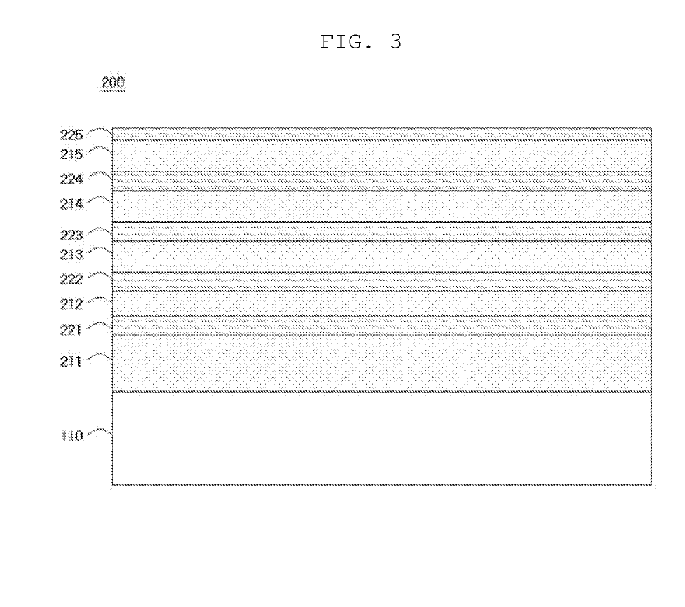

FIG. 3 is a cross-sectional view showing the structure of a multilayer thin film 200 according to an exemplary embodiment of the invention.

As shown in the figure, the multilayer thin film 200 includes a first low-refractivity thin film layer 211, a first high-refractivity thin film layer 221, a second low-refractivity thin film layer 212, a second high-refractivity thin film layer 222, a third low-refractivity thin film layer 213, a third high-refractivity thin film layer 223, a fourth low-refractivity thin film layer 214, a fourth high-refractivity thin film layer 224, a fifth low-refractivity thin film layer 215, and a fifth high-refractivity thin film layer 225, which are layered sequentially over the transparent substrate 110.

The high refractivity thin film layers can be made of one selected from the group consisting of TiO₂, Ta₂O₅, Ti₂O₃, Si₃N₄, Ti₃O₅, ZrO₂, Nb₂O₅, Diamond-Like Carbon (DLC), and a material such as DLC+Si or DLC+Ti, which contains DLC as a major component. The low-refractivity thin film layers can be made of one selected from the group consisting of SiO₂, MgF₂, DLC, and a material such as DLC+Si or DLC+Ti, which contains DLC as a major component.

As is well known in the art, Amorphous Carbon Layers (ACLs) are classified into Polymer-Like Carbon (PLC), DLC, and Graphite-Like Carbon (GLC) depending on the ratio of sp² bonding and sp³ bonding. The refractive index and extinction coefficient of the thin film layer made of DLC or a material that contains DLC as a major component increase, as the ratio of power to pressure used in the deposition system rises. Accordingly, DLC or a material containing DLC as a major component can form either the high-refractivity thin film layers or the low-refractivity thin film layers according to deposition conditions.

Not only proper adjustment of the refractive index of the high- and low-refractivity thin film layers but also proper adjustment of the thickness of the thin film layers is essential in raising the transmittance of visible light and lowering the transmittance of ultraviolet and near infrared light. In the multilayer thin film 200 shown in FIG. 3, the thickness of one of the low-refractivity thin film layers 211 to 215 is formed to be thicker than that of any of the high-refractivity thin film layers 221 to 225 and to be one and half times thicker than that of any of the other low-refractivity thin film layers. In the multilayer thin film 200 according to an exemplary embodiment of the invention, the thickest layer of the low-refractivity thin film layers 211 to 215 is formed to have a thickness of 150 nm or more, and all of the high-refractivity thin film layers 221 to 225 are formed to have a respective thickness less than 150 nm.

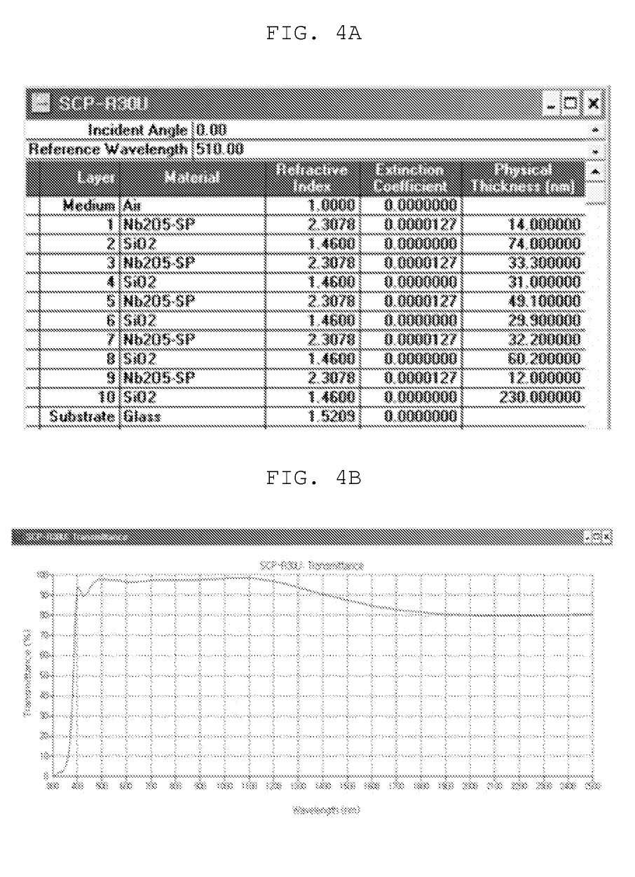

FIG. 4A is a view showing the physical properties of a multilayer thin film for a photovoltaic cell according to an exemplary embodiment of the invention, and FIG. 4B is a graph showing light transmittance, according to wavelength, of a transparent substrate having the multilayer thin film according to FIG. 4A.

First, referring to FIG. 4A, under conditions where a reference light source has a wavelength of 510 Å and the air is used as a light transfer medium, high-refractivity thin film layers, including Layer 1, Layer 3, Layer 5, Layer 7, and Layer 9, were made of Nb₂O₅ (niobium pentoxide), which has a refractive index of 2.3078 and an extinction coefficient of 0.0000127, and low-refractivity thin film layers, including Layer 2, Layer 4, Layer 6, Layer 8, and Layer 10, were made of SiO2 (silicon dioxide), which has a refractive index of 1.4600 and an extinction coefficient of 0.0000000.

In addition, in the high-refractivity thin film layers, the thicknesses of Layer 1, Layer 3, Layer 5, Layer 7, and Layer 9 were 14.0 nm, 33.3 nm, 49.1 nm, 32.2 nm, and 12.0 nm, respectively. In the low-refractivity film layers, the thicknesses of Layer 2, Layer 4, Layer 6, Layer 8, and Layer 10 were 74.0 nm, 31.0 nm, 29.9 nm, 60.2 nm, and 230.0 nm, respectively. In FIG. 4A, the thickness of the thickest low-refractivity thin film layer (Layer 10) was 230.0 nm.

Below, a description will be given of light transmittance, according to wavelength, of a transparent substrate having the multilayer thin film according to FIG. 4A. It can be appreciated that the transmittance is 30% or less in the range of light wavelength of 380 nm or less and that the transmittance is 90% or more in the range of light wavelength from 400 nm to 800 nm. Therefore, the multilayer thin film according to FIG. 4A can increase the life of the photovoltaic cell by blocking ultraviolet light, which otherwise would cause discoloration of an EVA sheet used in the photovoltaic cell, and raise the photovoltaic efficiency of the photovoltaic cell by raising the transmittance of visible light.

In addition, referring to the transmittance in the range of light wavelength of 1100 nm or more in FIG. 4B, the transmittance is 98% at 1100 nm and decreases gradually as the wavelength increases. In a wavelength range of 2000 nm or more, the transmittance is about 80%. As above, the multilayer thin film according to FIG. 4A has a function of blocking near infrared light of 1100 nm or more. Accordingly, the multilayer thin film can lower the working temperature and resistance of the photovoltaic element, thereby raising photovoltaic efficiency.

The foregoing descriptions of specific exemplary embodiments of the present invention have been presented for the purposes of illustration and description. They are not intended to be exhaustive or to limit the invention to the precise forms disclosed, and obviously many modifications and variations are possible in light of the above teachings. The exemplary embodiments were chosen and described in order to explain certain principles of the invention and their practical application, to thereby enable others skilled in the art to make and utilize various exemplary embodiments of the present invention, as well as various alternatives and modifications thereof. It is intended that the scope of the invention be defined by the claims appended hereto and their equivalents.

What is claimed is:

1. A multilayer thin film for a photovoltaic cell comprising a plurality of low-refractivity thin film layers and a plurality of high-refractivity thin film layers alternately coating a transparent substrate,
wherein the thickest layer of the low-refractivity thin film layers is thicker than all of the high-refractivity thin film layers and is one and half times thicker than all of the other layers of the low-refractivity thin film layers.

2. The multilayer thin film according to claim 1, wherein the thickest low-refractivity thin film layer has a thickness of 150 nm or more.

3. The multilayer thin film according to claim 1, wherein the thickest low-refractivity thin film layer has a refractive index ranging from 2.0 to 2.4.

4. The multilayer thin film according to claim 3, wherein the high-refractivity thin film layers are made of one selected from the group consisting of TiO₂, Ta₂O₅, Ti₂O₃, Si₃N₄, Ti₃O₅, ZrO₂, Nb₂O₅, diamond-like carbon, and a material containing diamond-like carbon.

5. The multilayer thin film according to claim 1, wherein the low-refractivity thin film layers have a refractive index ranging from 1.38 to 1.46.

6. The multilayer thin film according to claim 5, wherein the low-refractivity thin film layers are made of one selected from the group consisting of SiO₂, MgF₂, diamond-like carbon, and a material containing diamond-like carbon.
